(19) United States
(12) Patent Application Publication
(10) Pub. No.: US 2026/0264248 A1
(43) Pub. Date: Sep. 10, 2026

(54) SYSTEM AND METHOD FOR ROBOT CALIBRATION

(71) Applicant: ASML NETHERLANDS B.V., Veldhoven (NL)

(72) Inventors: Stijn Louis Willy LETERME, Herselt (BE); Aleksa TOPALOVIC, Aachen (DE); Mohamed Ahmed Abdelalim Hassan ALOSTA, Eindhoven (NL); Willem WILLEMSEN, Eindhoven (NL); Sebastianus Johannes ARTS, Asten (NL)

(73) Assignee: ASML NETHERLANDS B.V., Veldhoven (NL)

(21) Appl. No.: 19/491,373

(22) PCT Filed: Jun. 3, 2024
(86) PCT No.: PCT/EP2024/065159

§ 371 Date: Dec. 8, 2025

(30) Foreign Application Priority Data
Jun. 29, 2023 (EP) 23182417.8

(51) Int. Cl. B25J 9/16; B25J 9/00; B25J 11/00

(52) U.S. Cl. CPC B25J 9/1692; B25J 9/0087; B25J 9/1697; B25J 11/0095

(57) ABSTRACT

A method of calibrating a substrate handler, the handler including: a first substrate support and a second substrate support, a first robot arm related to the first substate support, and a second robot arm related to the second substrate support, wherein the first substrate support is provided with a first sensor, the first sensor being an edge sensor for sensing an edge of a substrate, a second sensor arranged at a predetermined distance with respect to the second substrate support, the second sensor being an optical sensor, the method including calibrating the first robot arm and the second robot arm with respect to the first substrate support and the second substrate support using the second sensor.

### CROSS-REFERENCE TO RELATED APPLICATION

The application claims priority of EP application 23182417.8 which was filed on 29 Jun. 2023 and which is incorporated herein in its entirety by reference.

### FIELD

The present invention relates to a method and system for calibration of a substrate handler. The substrate handler may comprise at least two substrate supports, and corresponding robot arms, each having a dedicated coordinate system. The method and system allow to calibrate the respective robot arms with respect to the substrate supports. Calibration may be required upon first use, periodically to compensate drift, or after replacement of parts. Calibration is intended to increase the accuracy of the robot to substrate positions in order to improve substrate transfer position accuracy. The system and method can be applied in a lithographic process. The substrate handler may be, for instance, an interface between a lithographic apparatus and other parts of the process such as the track or a metrology tool.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Substrates are typically transported between locations in a wafer handling system by robotic arms with grippers or other end effectors thereon. Locations to which a substrate may be transferred to and from may include: a substrate carrier or a device often referred to as a Front Opening Universal Pod (FOUP), where a plurality of substrates are stored, a support table (store unit) for temporary storage of substrates before and during processing steps, and an alignment support (pre-aligner), which may be used for one or more of aligning, centering and temperature conditioning of a substrate prior to a processing step.

Conventional wafer handling arrangements may typically comprise a load robot (LR) and an unload robot (UL), each with their own coordinate systems. Calibration of the wafer handler coordinate system (usually in at least a rotation (R), eccentricity (phi or φ), and height (z)) is needed for accurate takeover of substrates and efficient re-centering of substrates between respective locations. Calibration is, for instance, required upon start of use of a system, after each repair or replacement of a component, and periodically to compensate for drift.

Calibration is conventionally done via a mechanical reference, where each end-effector touches a positioning chuck on the alignment support multiple times, such that the robots can be calibrated relative to the alignment support position.

As disclosed in US20210291375A1, a calibration object is placed at a target orientation in a station of an electronics processing device by a first robot arm, and then retrieved from the station by the first robot arm. The calibration object is transferred to an aligner station using the first robot arm, a second robot arm and/or a load lock, wherein the calibration object has a first orientation at the aligner station. The first orientation at the aligner station is determined. A characteristic error value is determined based on the first orientation. The aligner station is to use the characteristic error value for alignment of objects to be placed in the first station.

US20050102064A1 discloses a substrate-handling robot which serves a processing tool, such as a plating tool, and which may be automatically controlled by a controller to perform a self-calibration procedure. As part of the procedure, an end effector of the robot is moved to interact with sensors provided on a calibration fixture that is positioned in a substrate placement location for which the calibration procedure is performed. The calibration fixture may have an opening formed therein to allow movement of the robot end effector within the calibration fixture. Sensor light beams generated by the sensors may interact with the end effector during the automatic calibration process so as to determine calibration data for the substrate placement location.

US20120136471A1 discloses a method for positioning substrates in a substrate processing apparatus having a substrate alignment device, a first substrate transport apparatus and a second substrate transport apparatus, includes calibrating the substrate alignment device with a motion of the first substrate transport apparatus, and calibrating a coordinate system of the second substrate transport apparatus with the substrate alignment device.

US20130218337A1 discloses a transfer system including a substrate positioning device, robots having a first robot and a second robot; and robot control devices, the robot control devices including a first robot control device to which the first robot and the substrate positioning device are connected and a second robot control device to which the second robot is connected. The first robot control device includes an acquiring unit configured to acquire, from the substrate positioning device, at least an absolute deviation amount between the rotation center of the mounting table and a center position of the substrate positioned, and a transmitting unit configured to transmit correction information relying on the absolute deviation amount acquired by the acquiring unit, to the second robot control device to which the second robot is connected.

As lithographic processes operate in a fast evolving business, wherein throughput of substrates per unit of time is of utmost importance and margins of legacy equipment drop due to increasing throughput of newer machines, the lithographic apparatus itself is constantly being assessed to include any potential further optimization, to gain improvements in throughput and speed. However, every optimization in one section of the apparatus may influence other sections, requiring re-design or re-positioning of modules or parts thereof. A potential alternative arrangement for the pre-aligner may mean that end-effectors can no longer access a mechanical positioning reference to make a mechanical reference contact for calibration. A new method of calibrating the substrate handler robot is therefore required.

### SUMMARY

The present disclosure provides a method of calibrating a substrate handler, the handler comprising:
a first substrate support and a second substrate support, a first robot arm related to the first substate support, and a second robot arm related to the second substrate support,
wherein the first substrate support is provided with a first sensor, the first sensor being an edge sensor for sensing an edge of a substrate,
a second sensor arranged at a predetermined distance with respect to the second substrate support, the second sensor being an optical sensor,
the method comprising the step of calibrating the first robot arm and the second robot arm with respect to the first substrate support and the second substrate support using the second sensor.

In an embodiment, the second sensor is arranged adjacent to the second substrate support.

In an embodiment, the first substrate support is a pre-aligner system comprising functionality to measure and correct eccentricity and orientation of a substrate positioned on the first substrate support.

In an embodiment, the method comprises the step of calibrating comprising calibrating a first end effector of the first robot arm and a second end effector of the second robot arm with respect to the second sensor.

In an embodiment, the step of calibrating the first end effector and the second end effector with respect to the second sensor comprises positioning a first opening of the first end effector and a second opening of the second end effector between an optical source and a sensor part of the second sensor.

In an embodiment, the step of calibrating comprises calibrating the second robot arm with respect to the substrate storage location using a third sensor provided at the storage location.

In an embodiment, the method comprises the steps of:
docking the first robot arm at the first substrate support;
using the second robot arm to pick up a substrate, move the substrate to the first substrate support;
positioning the substrate on the first substrate support;
using the first sensor and the first substrate support to center the substrate and direct the substrate in a predetermined orientation on the first substrate support;
picking up the substrate from the first substrate support using the first robot arm.

In an embodiment, the method comprises the steps of:
using the first robot arm to move the substrate to the second substrate support;
using the second robot arm to pick up the substrate from the second substrate support, and to move the substrate to the first substrate support;
using the first sensor to measure the eccentricity of the substrate with respect to the first substrate support;
using the eccentricity to calculate an offset of the second robot arm;
using the offset to calibrate the second robot arm with respect to the first substrate support.

In an embodiment, the method comprises the steps of:
determining a rotation of an unload robot coordinate system of the second robot arm with respect to a pre-aligner coordinate system of the first substrate support; and
correcting said rotation such that axes of the unload robot coordinate system are parallel to axes of the pre-aligner coordinate system.

In an embodiment, the method comprises the steps of:
using the second robot arm to pick up a substrate from a storage location;
move the substrate to the second sensor;
using the second sensor to detect a number of edge locations along a section of the circumference of the substrate;
using the number of edge locations to estimate a location of the substrate center;
using the second robot arm to position the substrate on the second substrate support;
move the second robot arm to the estimated location of the substrate center; and
using the second robot arm to pick up the substrate and move the substrate to the first substrate support.

In an embodiment, the step of using the number of edge locations to estimate a location of the substrate center comprises using a least square circle regression.

In an embodiment, the method comprises the steps of:
using the first sensor to perform a first measurement of the eccentricity of the substrate with respect to the first substrate support;
using the second robot arm to move the substrate at least one step in a radial direction on the first substrate support; and
performing at least a second measurement of the eccentricity of the substrate with respect to the first substrate support;
using the first measurement and the at least one second measurement to calculate a second offset; and
using the second offset to calibrate the second robot arm with respect to the first substrate support.

In an embodiment, the at least one step in a radial direction is in the order of 1 mm.

According to another aspect, the disclosure provides a handler system for substrates, comprising:
a first substrate support, comprising a first sensor being an edge sensor;
a first robot arm related to the first substrate support;
a second substrate support;
a second robot arm related to the second substrate support;
a second sensor, being an optical sensor, arranged at a predetermined location with respect to the second substrate support, the second sensor being adapted to calibrate the first robot arm and the second robot arm with respect to the first substrate support and the second substrate support.

According to yet another aspect, the disclosure provides a lithographic system, comprising at least one lithographic apparatus connected to at least one handler system as referenced above.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic top view of an exemplary substrate handler;

FIG. 3 depicts a schematic top view of an embodiment of a substrate handler;

FIG. 4 depicts a schematic side view of a substrate table, for instance a pre-aligner unit;

FIG. 5A depicts a schematic top view of a robot arm of a substrate handler to exemplify the corresponding coordinate system;

FIG. 5B depicts a schematic side view of the robot arm of FIG. 5A indicating respective coordinates and freedom of movement within the corresponding coordinate system;

FIGS. 6 to 18 depict respective steps of an embodiment of a method according to the disclosure; and

FIGS. 19 to 26 depict respective steps of another embodiment of a method according to the disclosure.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

The term “pre-aligner” as employed in this text may be broadly interpreted as a device, which provides accurate, non-contact measurement of the eccentricity and orientation of substrate placement. The device can be integrated with other substrate-manipulating devices. The pre-aligner is used to provide high alignment accuracy to correct a wide range of initial substrate-misplacement. The operations of the pre-aligner may include wafer displacement measurement, calculation of the necessary compensation, and orientation of a notch (or a flat) of the substrate to a desired angle. The pre-aligner may be provided with a high-resolution encoder to provide a desired accuracy of the chuck-movement, allowing very precise alignment of a wide range a substrate displacement.

The term “docking” or “docked” as employed in this text may be broadly interpreted as referring to an end effector of a respective robot arm being at a predetermined location, i.e. the docking location, at a corresponding substrate support, such as the pre-aligner. Docking typically provides a mechanical means for accurate alignment of the robot arm with respect to the docking location. The term “undocked” as employed herein may refer to the opposite, wherein the respective end effector is released from said docking location. Said docking location is typically known relatively accurately in respect to the location of the respective substrate support.

The term “docking location” may refer to a position wherein the respective end effector is positioned at a center location of a corresponding substrate support. This may generally imply that a substrate which is centered on the end effector will also be centered on the substrate support when the substrate is transferred from the end effector to the substrate support, and vice versa.

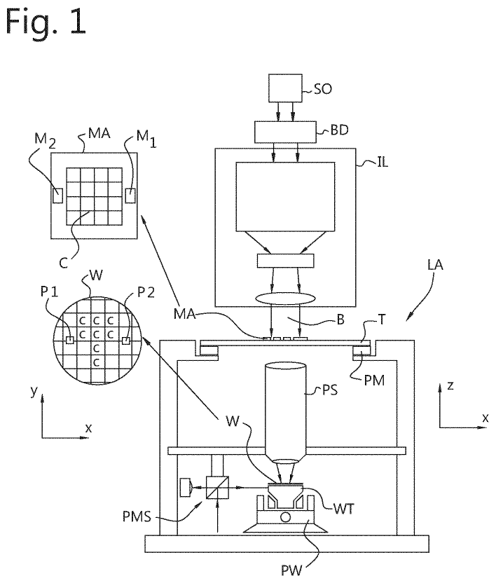

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

As depicted in FIG. 1, the lithographic apparatus is of a transmissive type (e.g. employing a transmissive mask and/or transmissive optical elements such as lenses). Alternatively, the lithographic apparatus may be of a reflective type (e.g. employing a programmable mirror array as optical elements, and/or employing a reflective mask).

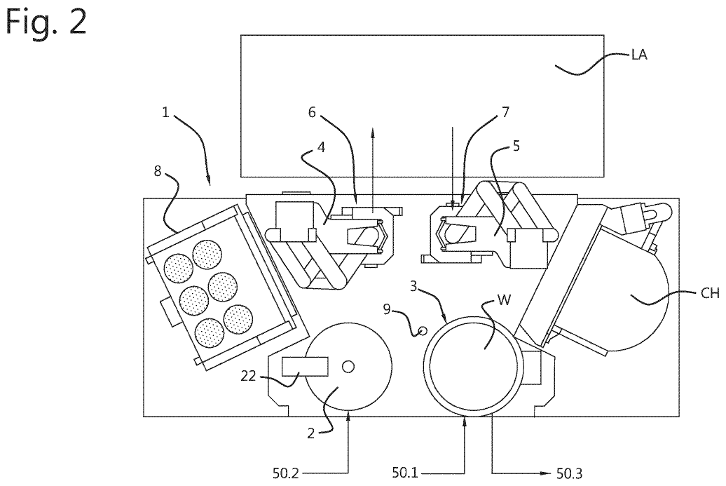

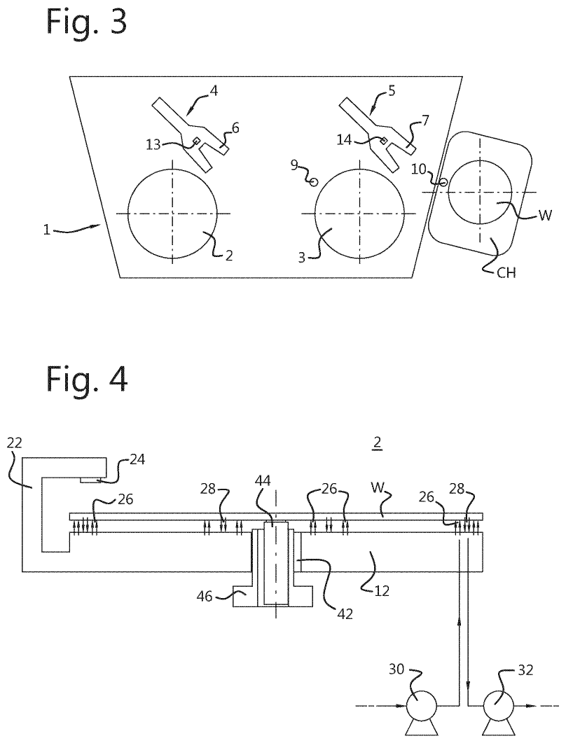

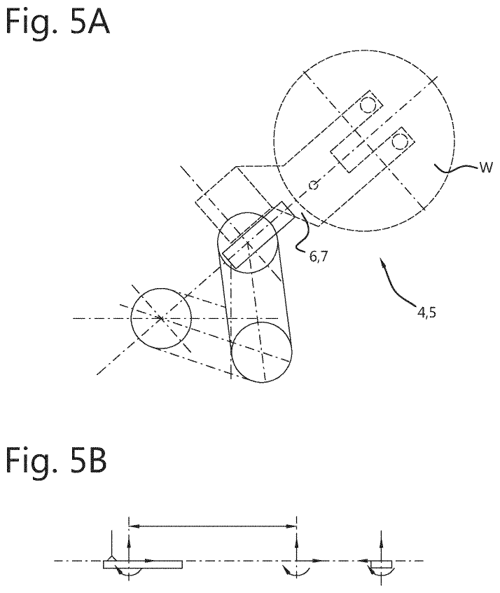

FIGS. 2 and 3 show a handler 1 for handling substrates W. The substrate handler 1 may comprise one or more substrate supports 2, 3. A first substrate support 2 may be provided with a first robot arm 4. A second substrate support 3 may be provided with a second robot arm 5. Each robot arm may have one end connected to a motor for moving the arm, and an opposite end for engaging the substrate. Said opposite end may also be referred to as an end effector. One or more of the robot arms may have multiple end effector ends, enabling one robot arm to engage multiple substrates. Said end for engaging the substrate may be referred to as an end effector 6, 7.

The first substrate support 2 may be a pre-aligner unit PA. An example and generic description of a pre-aligner unit PA is provided below with respect to FIG. 3. The corresponding first robot arm 4 may be referred to as a load robot LR. The second substrate support 3 may be a storage unit SU. The storage unit SU may function as a temporary storage for substrates within the substrate handler 1 in between processing steps. The corresponding second robot arm 5 may be referred to as an unload robot UR. Optionally, the storage unit or substrate support 3 may also include a Thermal Stabilization Unit (TSU), for stabilizing and adjusting the temperature profile of a substrate positioned on the substrate support 3.

The respective parts of the handler can move with respect to each other. As such, movements of each part are typically expressed in a dedicated coordinate system, including translation (x, y, z) and rotation (Rx, Ry, Rz). The handler as exemplified in FIG. 2A may have at least four coordinate systems, i.e. a load robot coordinate system (LRCS), an unload robot coordinate system (URCS), pre-aligner coordinate system (PACS), and a storage unit coordinate system (SUCS).

The substrate handler may be arranged adjacent to other units or other equipment of a lithographic process, such as a substrate carrier CH. The robot arms 4, 5 can move the substrates around, to and from the other equipment and to and from the substrate support tables 2, 3 in the handler 1. Please note that the substrate carrier as depicted is positioned adjacent to the second substrate support. However, other equipment can be positioned on either side of the handler 1. Herein, the substrate handler 1 may typically function as an interface between the respective equipment units. For instance, the handler may function as an interface between a so-called track, basically an overhead conveyor belt system for carrying pods with substrates between respective process steps of the lithographic process, and the lithographic apparatus as exemplified in FIG. 1. The track may be positioned, for instance, on one side of the substrate handler 1 while the substrate stage of the respective lithographic apparatus is positioned adjacent to another side. Typically, a vacuum load lock or other loading device is positioned between the handler and the track. The first and second robot arms 4, 5 can pick up a respective substrate W in the substrate carrier or from the track, move the respective substrate to one of the first substrate support 2 or the second substrate support 3, to the lithographic apparatus, and vice versa.

FIG. 2 shows an exemplary wafer handler for conditioning and aligning wafers prior to a processing step in a lithographic process, such as measurement and exposure. The handler 1 comprises two robots 4, 5. Referring to FIG. 3, each robot 4, 5 may have an end effector 6, 7. The first substrate support 2 is a pre-aligner (alignment support). The handler includes a second substrate support 3 (a storage unit for temporary substrate support and storage). A substrate carrier CH may be included. Rejected substrates may be stored in the substrate carrier, which may include a cassette such as a FOUP. The substrate carrier CH can also be used during scanner system calibration, testing, diagnostics and even to run production from the carrier. The wafer handler may include a control cabinet 8 with control software (see FIG. 2). On the bottom of the illustration (as shown in FIG. 2) is where a track would be located, where all the substrates for measurement and exposure are entering and leaving the handler, as exemplified by arrows 50.1-50.3. References 50.1 and 50.2 for instance exemplify a flow of substrates from the track into the handler (50.2 is an optional flow directly to the pre-aligner), and reference 50.3 exemplifies a flow of processed substrates out of the handler 1 onto the track. Bear in mind this is for substrates that are to be or have been measured and exposed or otherwise processed in the lithographic apparatus LA. Another flow may be used for the calibration of wafers that are stored in the substrate carrier CH. On the top side of FIG. 2 is the ‘processing unit’ or the lithographic apparatus LA where measurement and exposure of the aligned and conditioned substrates takes place.

For further technical details regarding the setup and operation of a substrate handler and the corresponding robot arms in combination with a track and a lithographic apparatus, reference is made to, for instance, U.S. Pat. No. 7,345,736-B2.

As refenced above, the first substate support may be a pre-aligner unit PA. The pre-aligner positions substrates accurately before they are transferred onto an exposure platform, such as the substrate table WT. The positioning accuracy of the pre-aligner may affect the exposure accuracy of the substrate and the work efficiency of the entire lithographic process. The position herein typically refers to both rotation and translation (eccentricity with respect to a center of the substrate support). In addition to positioning, the pre-aligner may condition the substrate, for instance by thermal control, i.e. controlling the temperature profile of the substrate before exposure.

The pre-aligner typically includes functionality to measure a position of the substrate W on the pre-aligner, and to adjust said position with respect to a reference, such as a center location. The position measurement may include an edge sensor for detecting an edge of the substrate. The PA can then determine the eccentricity, angular offset and magnitude of the offset (with respect to a perfectly centered position). The edge sensor is used to determine the geometric center and angular position of a substrate, for instance by measuring the location of the edge of a substrate while it is rotating. The edge scan thus determines the center of the substrate. In addition, each substrate may be provided with a notch at one location on the edge of the respective substrate. A notch scan can determine the angular position of the wafer.

Pre-aligner units can be obtained from multiple companies, such as Kensington Laboratories, LLC [USA], Genmark Automation Inc. [CA], SUSS MicroTec SE [Germany], and via Wafer-Handling. com [California, USA].

FIG. 4 shows an exemplary pre-aligner 2 for aligning a substrate W. The system comprises a support table 12 for supporting the substrate. The table has a centrally located opening 42. A rotatable support unit 44 is movable in vertical direction through the centrally located opening 42 of the support table 12. The support unit 44 may also be referred to as a pre-alignment chuck or p-chuck. An alignment support 46 may extend through another opening, or be co-located with the central support unit 44. The alignment support unit 46 is moveable in a radial direction with respect to the rotatable unit 44. An edge detection unit 22 may be provided, comprising a sensor 24. The sensor may be an optical sensor, such as a CCD camera. The optical sensor 24 typically cooperates with a light source, such as a laser or other source of focused light.

A top surface of the support table 12 may be provided with openings 26, 28. The openings 26, 28 may be connected to respective pumps, allowing to expel gas or suck in gas respectively. The first openings 26, connected to a first pump 30 expelling air through the respective openings, allow to create an air bearing allowing the substrate to float on the support table. The second openings 28, connected to a second pump 32 for sucking in air or gas, allow to clamp the substrate to the support table 12 using pressure reduction. The air bearing created by the air expelled out of openings 26 allows the wafer W to be rotated while clamped (for instance due to the vacuum created by openings 28) and conditioned.

In use, typically, the substrate W is rotated while the edge is measured using the optical sensor 24. Herein, an edge of the substrate may typically be provided with characterizing features, such as a notch, allowing positioning based on optical sensing. Using the information provided by the optical sensor 24, the wafer alignment (x, y, Rz) is calculated and can be corrected. The pre-aligner may have a measurement accuracy in the order of 1 to 5 μm. The centering unit 46 can move the substrate in a radial direction to correct eccentricity. The centering unit may have an accuracy in the order of tens of μm. The edge scan unit 22 can measure alignment residue which may be further corrected at wafer stage level. After the measurement, the substrate W can be rotated using the rotatable unit 44. A substrate may typically be provided with a notch or other positioning marker, allowing the notch to be detected and subsequently directed in a predetermined orientation.

Optionally, the substrate support table 12 may include a Thermal Stabilization Unit (TSU). The TSU allows to set a temperature profile of the substrate, typically a substantially uniform temperature across the entire substrate, during pre-alignment.

The rotatable unit 44 and the translation unit 46 may be connected to respective encoders. Due to the micrometer scale accuracy required for a lithographic process, the encoders are typically relatively large units.

As referenced in the introduction, the one or more robot arms 4, 5 may have to be re-calibrated at times with respect to the respective substrate supports. For instance, when the substrate handler 1 is started after maintenance, after replacement of parts, or upon first use. Herein, the handler 1 may include a calibration sensor 9 (see FIGS. 2 and 3). The calibration sensor 9 may be arranged adjacent to the second substrate support 3. An optional second calibration sensor 10 may be provided adjacent to the substrate carrier CH. In a practical embodiment, the first calibration sensor 9 is an optical sensor. The sensor may comprise a light source, such as a laser or lamp, and a corresponding detector. The sensor 9 is preferably located adjacent to the store unit (SU).

The light source and detector of the calibration sensor 9 may be co-located. Herein, the detector may detect reflected light originating from the light source. Alternatively, the light source of the calibration sensor 9 may be located in a plane below each end-effector 6, 7 of the first and second robot arms 4, 5. The detector is typically located opposite the light source in a plane above each end-effector 6, 7. In an embodiment, the end-effectors 6, 7 each comprise a small opening 13, 14. The location of the openings 13, 14 in the respective end-effector is known. Herein, the location of said openings 13, 14 could be pre-calibrated with respect to the coordinate system of the respective robot arm. The light of the light source can propagate through the opening 13, 14 when the hole is positioned above the light source. When this happens, the light of the light source can be detected by the detector and the end-effector position can be calibrated relative to the position of the light source of the calibration sensor 9. In a practical embodiment, the light source and detector of the calibration sensor scan edges of the openings 13, 14 and as such find the respective position. The latter provides a more accurate result.

In a method of the disclosure, the end-effectors of each of the load robot LR and unload robot UR are calibrated with reference to the calibration sensor 9.

The end-effector 6 of the first robot arm 4, i.e. the load robot LR, may have an additional calibration mechanism to calibrate it relative to the pre-aligner PA. Thus, the LR can also be calibrated with respect to the pre-aligner PA. What is needed is a way to calibrate the unload robot UR with respect to the pre-aligner PA and thus relative to the LR.

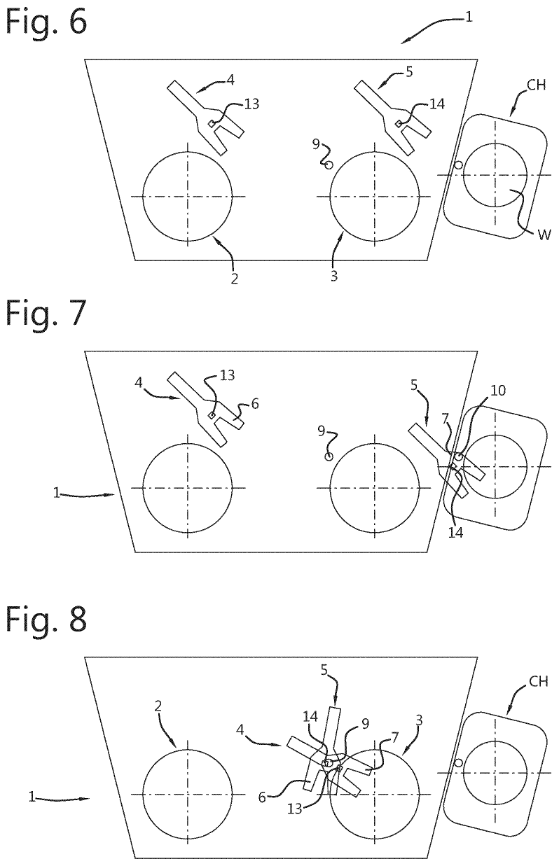

Embodiments of a method to calibrate the substrate handler will be described herein below, generally referring to FIGS. 6 to 26. Calibration of a respective robot arm herein may include one or more of calibration of translation, rotation, and height (referred to as R, phi and Z calibration). In a preferred embodiment, rotation and orientation (R, phi) are calibrated. Z may already be known sufficiently accurate.

FIG. 6 shows the handler 1, with parts as described above with respect to FIGS. 2 and 3. One or more substrates W may be provided in a generic storage location, such as the substrate carrier CH. These substrates may be specifically intended for the calibration process, and as such may be dummy substrates rather than wafers to be irradiated and patterned.

In a first step, see FIG. 7, the second robot arm 5 may be calibrated with respect to the storage location using the second calibration sensor 10. As the position of the second calibration sensor 10 is known with respect to the substrate carrier CH, the position of the end effector 7 of the second robot arm 5 is also known, for instance when the opening 14 aligns with the sensor 10. This optional step may be included to allow accurate takeover of a substrate W from the storage location.

Generally referring to FIG. 8, a sequence for calibrating the respective robot arms 4, 5 with respect to the substrate supports 2, 3 may start with calibrating one or more of the end effectors 6, 7 of the robot arms with respect to the first calibration sensor 9. Both end effectors will be calibrated with respect to the second substrate support 3. The calibration sensor 9 can be used to calibrate all robot arms. Alternatively, other calibration methods can be used, using calibration sensor 9 only to calibrate the unload robot UR (the second robot arm 5). for example. The respective end effectors may be calibrated at the same time, or one after the other. As the position of the first calibration sensor 9 is known with respect to the location of the second substrate support 3, the position of the end effectors 6, 7 of the robot arms 4, 5 is also known. Calibration herein may involve positioning the respective end effectors 6 and 7 at the location of the first calibration sensor 9, such that the respective openings 13 and 14 align with the optical sensor and its light source. When the position of the openings 13, 14 is determined with the sensor 9, the position to the respective end effectors is available, as the location of the sensor 9 is known.

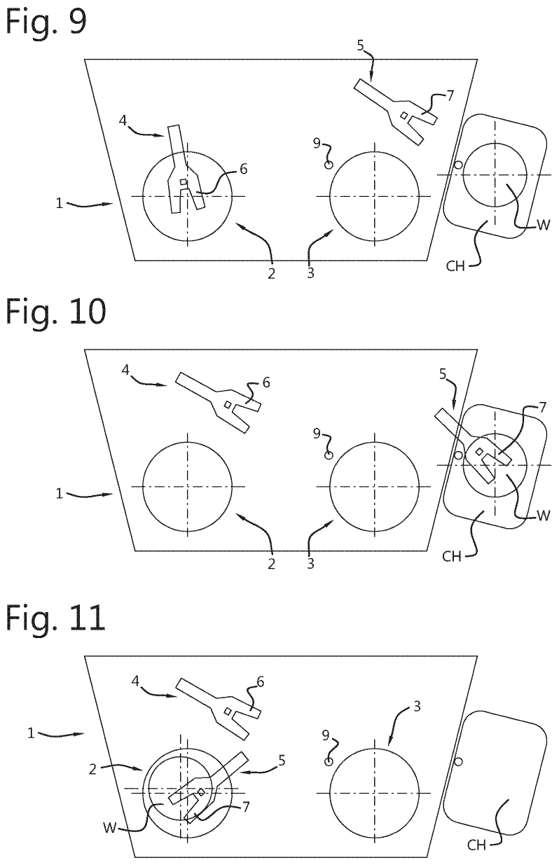

In a subsequent step, see FIG. 9, the first end effector 6 may be docked at the docking location of the pre-aligner 2. As the location of the docking location of the first substrate support 2 is known (in the coordinate system of the first substrate support), subsequently the location of the first end effector 6 with respect to the first substrate support is also known. I.e., docking the first end effector 6 at the first substrate support 2 allows docked calibration of the first robot arm 4.

Subsequently, the second end effector 7 can pick up a substrate W from a location of choice, such as the substrate carrier CH. See FIG. 10. At said location of choice, substrates W may generally be slightly off center. For instance, the substrate carrier may comprise a stack of substrates, each having a different eccentricity. As a result, the substrate W picked up by the second end effector 7 may be eccentric with respect to the center of the second end effector 7.

Generally referring to FIG. 11, next the second robot arm 5 may move the substrate to the first substrate support 2. The substrate is transferred from the second end effector 7 onto the first substrate support 2. The substrate W was eccentric with respect to the second end effector 7, and is also eccentric with respect to the first substrate support 2.

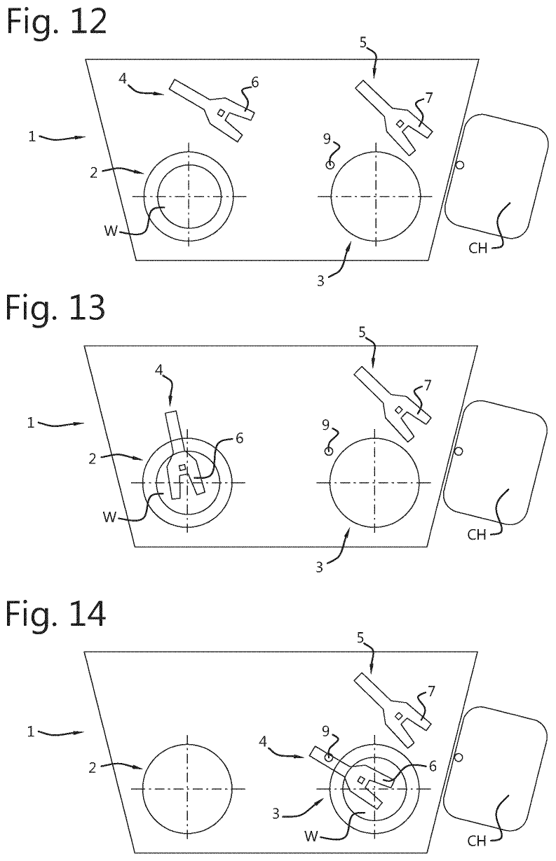

As exemplified above in conjunction with FIG. 4, the first substrate support 2 may typically be provided with functionality to measure and subsequently correct the eccentricity of the substrate W. As generally depicted in FIG. 12, in a next step the substrate W as positioned on the first substrate support 2 is centered with respect to the center of the first substrate support.

Next, see FIG. 13, the first end effector 6 of the first robot arm 4 docks at the first substrate support 2. The docking position is typically centrally located with respect to the first substrate support 2. Thus, with the end effector docked, the substrate W and the first end effector 6 are centered with respect to the top surface of the first substrate support 2. Then, the first end effector 6 picks up the centered substrate W from the first substrate support 2.

Generally referring to FIG. 14, the first robot arm 4 subsequently moves the substrate W to the second substrate support 3. The substrate is transferred to the second substrate support 3. As the first robot arm had been calibrated with respect to the calibration sensor 9, the first robot arm can position the substrate at the center of the second substrate support. Herein, the substrate is perfectly centered on the second substrate support within the accuracy margin of the first robot arm 4 and its end effector 6.

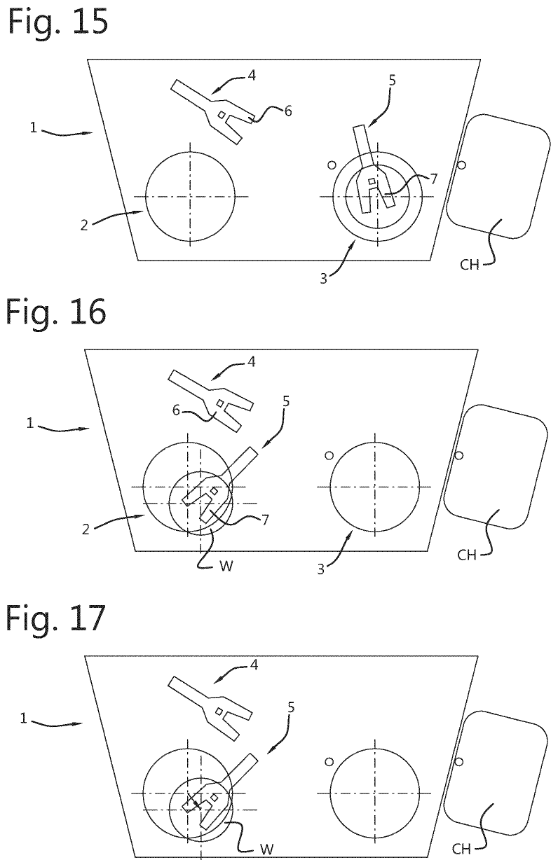

Referring to FIG. 15, subsequently the second robot arm 5 picks up the centered substrate W from the second substrate support 3. As referenced above, one or both of the robot arms may have been calibrated with respect to the calibration sensor 9 and hence to the center of the second substrate support 3. As a consequence no eccentricity is added to the substrate with respect to the respective end effector in this step (within tolerances).

Referring to FIG. 16, the second robot arm 5 moves the substrate W, which is now centered on its end effector 7, to the first substrate support 2. The substrate W is transferred onto the first substrate support 2. Then, the offset of the substrate W with respect to the center of the first substrate support 2 is measured. Measuring the offset may include measuring the eccentricity, typically involving the edge sensor 24 of the first substrate support 2. Also the position of the center of the substrate with respect to the center of the first substrate support can be determined. The latter typically includes a vector, including a length and a direction, potentially expressed as a rotation. After or during the position measurement, the substrate may be centered with respect to the first substrate support. Alternatively, the substrate W may remain in its eccentric position.

Referring to FIG. 17, in a subsequent step the offset of the substrate with respect to the center of the first substrate support 2 is translated onto the coordinate system of the second robot arm 5.

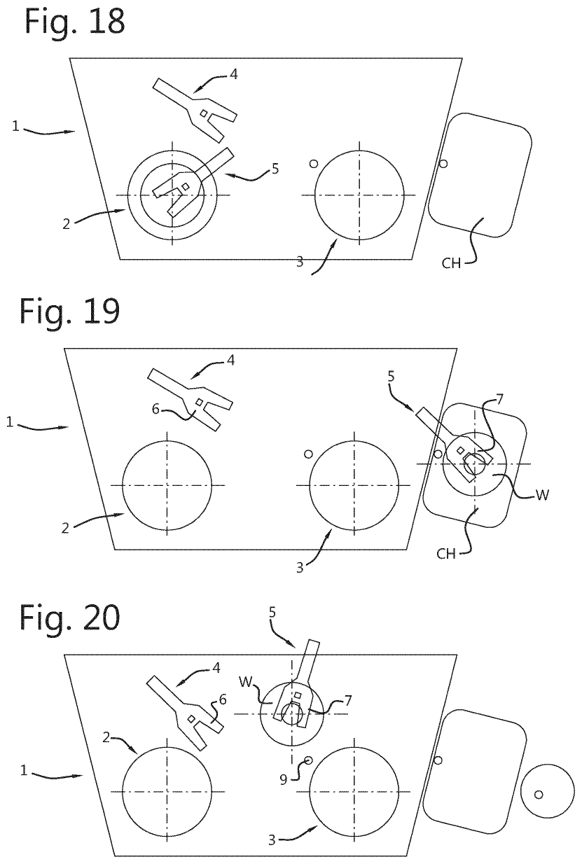

Generally referring to FIG. 18, the offset is used to correct the position of the center of the coordinate system of the second robot arm, i.e. the unload robot coordinate system (URCS), with respect to the center of the pre-aligner coordinate system (PACS). Correction herein may include a correction of rotation (R) and/or eccentricity (phi). The correction basically involves a translation of the center of the URCS to match with the center of the PACS. The translation is a vector, which can be expressed as rotation (angle) and eccentricity (length, amplitude) in the horizontal plane of the PACS. Alternatively, the translation can be expressed as an addition of translation along the x-axis and the y-axis of the PACS respectively.

In addition to the offset of the center of a respective coordinate system, both coordinate systems may also be rotated or tilted with respect to each other. Assuming a Cartesian coordinate system, the latter means that the respective axes of both coordinate systems may not be in parallel. The present disclosure proposes two options to deal with potential rotation of respective coordinate systems.

A first option is to translate the offset from the pre-aligner coordinate system (PACS) to the coordinates of the second robot arm (URCS), assuming that the orientation and position of the PA coordinate system with respect to the second robot arm 5 is known. As the orientation of the second robot arm, and thus of its coordinate system, may be slightly different than an assumed orientation, this option may introduce an error. In effect, the offset of the center of the URCS is corrected, but the orientation may only be corrected based on the known value of the orientation.

In another option, the orientation of both coordinate systems may be described with respect of each other. Details of this option are described with reference to FIGS. 25A and 25B below. The same steps may be included in the embodiment shown in and described with respect to FIGS. 6 to 18.

Finally, the offset as translated onto the unload robot coordinate system URCS is used to correct the position of the second robot arm with respect to the first substrate support. The latter basically calibrated the second robot arm 5 with respect to the first substrate support 2. The calibrated second robot arm can now pick up the centered substrate W from the first substrate support.

Generally referring to FIG. 19 and further, other embodiments are possible as well. A second embodiment starts with the steps shown in and described with respect to FIGS. 6 to 8. In FIG. 8, the end effectors 6, 7 of the first and second robot arm 4, 5 were calibrated with respect to the first calibration sensor 9. Referring to FIG. 19, in a next step, the second robot arm 5 picks up a substrate from a location of choice, such as the substrate carrier CH. As referenced before, the substrate as stored is typically positioned somewhat eccentric, and thus will also be off-center when positioned on the robot arm.

Referring to FIG. 20, the second robot arm 5 moves the substrate W to the calibration sensor 9.

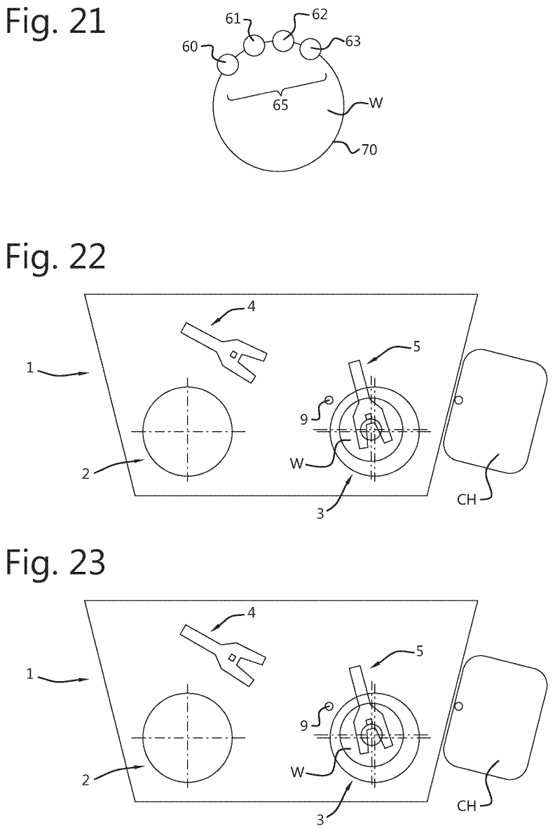

As exemplified in FIG. 21, the first calibration sensor 9 is used to scan at least a fraction of the edge of the substrate as positioned on the second end effector 7. For instance, scanning may involve measuring a number of points 60-63 on the edge of the wafer, for example at least three points up to any number of point as suitable within the constraints of the system, including for instance speed, time, accuracy, and substrate shape. As the calibration sensor 9 may be an optical sensor, measuring the edge of the substrate herein may involve repeatedly moving the second end effector 7 with the substrate W positioned on it into and out of the light beam of the optical source of the calibration sensor, allowing the sensor to measure when the light beam is interrupted or not. The step between said interruption and a detected light source will be recorded as one of the measurement points 60-63 as indicated in FIG. 20. Herein, measurement samples may be obtained over a certain edge scan region 65 of the substrate. Said edge scan region may be in the range of covering 10 to 50%, for instance about 20 to 30%, of the circumference 70 of the substrate W.

The center of the substrate W can be calculated based on the measurement points 60-63 of the edge of the substrate. Multiple fit functions can be used to determine the center of the substrate. For instance, using a least square circle regression, the position of the center of the substrate can be calculated. When the position of the center of the substrate is defined, the magnitude and direction of the eccentricity of the substrate W with respect to the second end effector 7 is known. Other circle regression methods are described in, for instance, “Régressions coniques, quadriques, circulaire, sphérique”, published partly in magazine QUADRATURE no 63, pp. 33-40, January 2007; and partly in QUADRATURE no 65, pp. 4-5, July 2007.

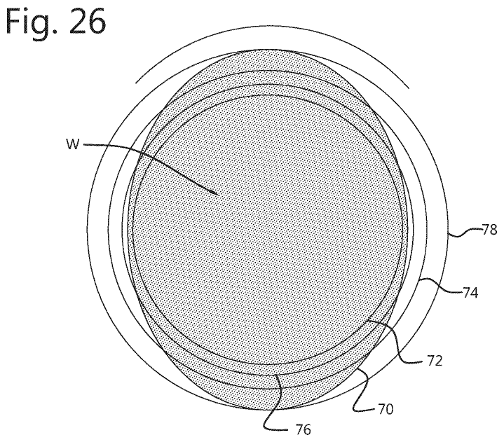

The substrate shape, see FIG. 26 for an example, may generally be round. However, at the level of accuracy involved in lithographic processes, which is typically in the range of micrometers down to nanometer level, said generally round shape may turn out to be slightly off. For instance, a circumference 70 of the substrate may be slightly elliptical. In FIG. 26, several circular lines indicate various potential outcomes of a regression technique, depending on the number of measurement points and the position on the circumference thereof. Outcomes may range from a minimum substrate diameter 72, a nominal substrate diameter 74, and an intermediate diameter 76 to a maximum substrate diameter 78.

In case the wafer edge scan region would cover only a certain amount of degrees of the circumference 70 and in case the substrate would be elliptical up to the diameter tolerance of the substrate (+/−0.2), see oval line 70 in FIG. 26, a center offset will be detected. The accuracy of the regression can be improved by, for instance, widening the edge scan region 65. Maximum accuracy can be obtained by widening the edge scan region up to or exceeding at least half of the circumference of the substrate.

Subsequently, see FIG. 22, the second robot arm moves the substrate W to the second substrate support and transfers the substrate from its end effector 7 onto the second substrate support 3.

When the substrate is positioned on the second substrate support, the second end effector 7 is moved to the coordinates of the substrate center. Said substrate center can be calculated using the circumference which was determined as described above. See FIG. 23. The second end effector then picks up the substrate W from the second substrate support 3. The substrate W is now centered on the second end effector 7.

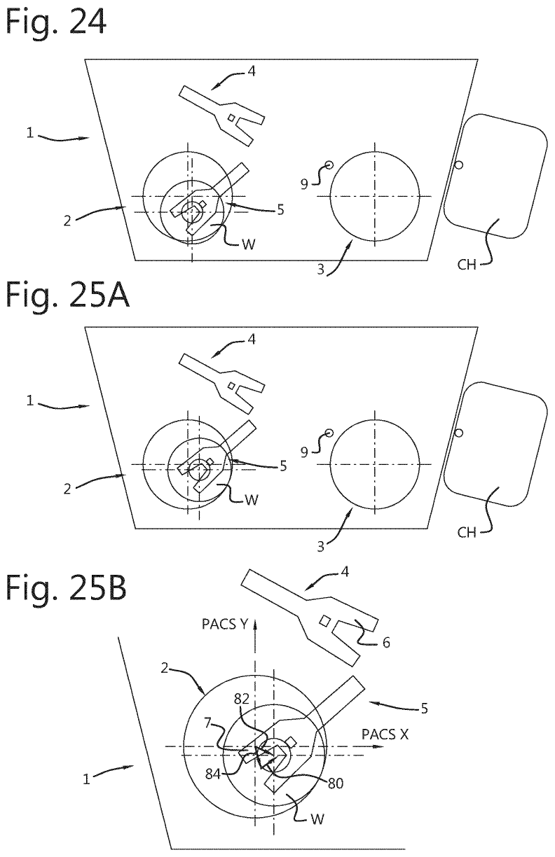

Generally referring to FIG. 24, the second robot arm 5 moves the substrate to the first substrate support 2. The substrate is positioned on said first substrate support, i.e. the substrate is transferred from the second end effector 7 onto the first substrate support 2.

Referring to FIG. 25A, the first substrate support 2 subsequently measures the eccentricity of the substrate, including magnitude and direction. The eccentricity is not corrected. Any pre-align error is actually due to a potential position error of the second robot arm with respect to the first substrate support 2. So, the substrate was centered on the second end effector 7 of the second robot arm 5.

Referring to FIG. 25B, the latter steps of placing the substrate on the first substrate support 2, measuring the eccentricity, using the second robot arm 5 to pick up the substrate is repeated several times. Herein, after the second robot arm 5 has picked up the substrate from the first substrate support 2, the second robot arm moves its second end effector 7 slightly, exemplified by arrow 80. Herein, step 80 is a defined movement. Next, the substrate W is placed on the first substrate support and the eccentricity 82 is measured once more. The movement 80 may be in the order of 1 mm. The movement 80 may be in a rotational direction with respect to the center of the first substrate support 2. The defined move 80 may be in a radial direction of the unload robot, while its orientation (phi) is constant. Herein movement of the respective robot arms can be expressed as a movement in radial direction (R) and a rotation (phi) with respect to a center of rotation of the robot arm. As the length and direction of the movement along arrow 80 is known, solving the triangle indicated by respective arrows 80, 82 and 84 provides information about a rotational offset of the URCS. Herein, the length and orientation of arrows 82 and 84 result from respective eccentricity measurements by the first substrate support 2. For instance, the movement 80 can be a retraction of the second robot arm, with its rotation kept constant. The triangle formed by arrows 80, 82 and 84 enables to calculate a value h, using the Pythagorean theorem: a²+b²=c². Herein, h is the length of the side of a right angle triangle, originating from the center of the first substrate support towards and perpendicular to arrow 80, and can be substituted for side b in the theorem. Arrows 82 and 84 can be substituted for the c in the theorem, for respective right angle triangles on either side of h. The step of arrow 80 is part of section a of the two triangles. With x representing the radial length of the triangle base, i.e. the location where line h intersects arrow 80, the rotational correction of the second robot arm can be expressed as: Phi correction=atan(h/x). Based on the outcome, a calibration correction for the second robot arm 5 with respect to the substrate W can be calculated. Said calibration correction can include both a radial component and a rotation with respect to a center of rotation of the second robot arm 5. Alternatively or in addition, the calibration correction can include a radial component and an angular component with respect to the center of the first substrate support 2. The steps exemplified in FIG. 25B correspond to the second option as described above, allowing a correction of the orientation of the URCS with respect to the PACS, in addition to correction of the offset of the center of the URCS.

In an embodiment, the sequence of steps described with respect to FIGS. 25A and 25B can be repeated for the first robot arm 4. The latter may be useful in case the first substrate support lacks a docking position.

The method and system of the present disclosure enable calibration of the unload robot (UR) and the load robot (LR) with respect to both the pre-aligner (PA) and the storage unit (SU) using a single added sensor. The method and system provide a reduction in capital expenditure as several hardware components are obviated. For instance, there is no need for robot wrist detection in the unload robot. Docking at a hardware item is obviated, while only one additional sensor is needed. Said sensor can be a relatively simple optical sensor.

The method and system are an enabler for an improved pre-aligner. The PA may, for instance, allow to remove the thermal stabilisation unit (TSU), resulting in further capex reduction, while enabling to handle relatively warped substrates.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set out as in the following numbered clauses.
1. A method of calibrating a substrate handler, the handler comprising:
   a first substrate support and a second substrate support, a first robot arm related to the first substate support, and a second robot arm related to the second substrate support,
   wherein the first substrate support is provided with a first sensor, the first sensor being an edge sensor for sensing an edge of a substrate,
   a second sensor arranged at a predetermined location with respect to the second substrate support, the second sensor being an optical sensor,
   the method comprising the step of calibrating the first robot arm and the second robot arm with respect to the first substrate support and the second substrate support using the second sensor.
2. The method of clause 1, wherein the second sensor is arranged adjacent to the second substrate support.
3. The method of clause 1 or 2, wherein the first substrate support is a pre-aligner system comprising functionality to measure and correct eccentricity and orientation of a substrate positioned on the first substrate support.
4. The method of one of the previous clauses, the step of calibrating comprising calibrating a first end effector of the first robot arm and a second end effector of the second robot arm with respect to the second sensor.
5. The method of clause 4, the step of calibrating the first end effector and the second end effector with respect to the second sensor comprising positioning a first opening of the first end effector and a second opening of the second end effector between an optical source and a sensor part of the second sensor.

6. The method of one of the previous clauses, the step of calibrating comprising calibrating the second robot arm with respect to the substrate storage location using a third sensor provided at the storage location.
7. The method of one of the previous clauses, comprising the steps of:
   docking the first robot arm at the first substrate support;
   using the second robot arm to pick up a substrate, move the substrate to the first substrate support;
   positioning the substrate on the first substrate support;
   using the first sensor and the first substrate support to center the substrate and direct the substrate in a predetermined orientation on the first substrate support;
   picking up the substrate from the first substrate support using the first robot arm.
8. The method of clause 7, comprising the steps of:
   using the first robot arm to move the substrate to the second substrate support;
   using the second robot arm to pick up the substrate from the second substrate support, and to move the substrate to the first substrate support;
   using the first sensor to measure the eccentricity of the substrate with respect to the first substrate support;
   using the eccentricity to calculate an offset of the second robot arm;
   using the offset to calibrate the second robot arm with respect to the first substrate support.
9. The method of clause 8, comprising the steps of:
   determining a rotation of an unload robot coordinate system of the second robot arm with respect to a pre-aligner coordinate system of the first substrate support; and
   correcting said rotation such that axes of the unload robot coordinate system are parallel to axes of the pre-aligner coordinate system.
10. The method of one of clauses 1 to 6, comprising the steps of:
   using the second robot arm to pick up a substrate from a storage location;
   move the substrate to the second sensor;
   using the second sensor to detect a number of edge locations along a section of the circumference of the substrate;
   using the number of edge locations to estimate a location of the substrate center;
   using the second robot arm to position the substrate on the second substrate support;
   move the second robot arm to the estimated location of the substrate center; and
   using the second robot arm to pick up the substrate and move the substrate to the first substrate support.
11. The method of clause 10, the step of using the number of edge locations to estimate a location of the substrate center comprising using a least square circle regression.
12. The method of clause 10 or 11, comprising the steps of:
   using the first sensor to perform a first measurement of the eccentricity of the substrate with respect to the first substrate support;
   using the second robot arm to move the substrate at least one step in a radial direction on the first substrate support; and
   performing at least a second measurement of the eccentricity of the substrate with respect to the first substrate support;
   using the first measurement and the at least one second measurement to calculate a second offset; and
   using the second offset to calibrate the second robot arm with respect to the first substrate support.
13. The method of clause 12, the at least one step in a radial direction being in the order of 1 mm.
14. A handler system for substrates, comprising:
   a first substrate support, comprising a first sensor being an edge sensor;
   a first robot arm related to the first substrate support;
   a second substrate support;
   a second robot arm related to the second substrate support;
   a second sensor, being an optical sensor, arranged at a predetermined location with respect to the second substrate support, the second sensor being adapted to calibrate the first robot arm and the second robot arm with respect to the first substrate support and the second substrate support.
15. A lithographic system, comprising at least one lithographic apparatus connected to at least one handler system according to clause 14.

1. A method of calibrating a substrate handler, the handler comprising:
a first substrate support and a second substrate support,
a first robot arm related to the first substate support,
a second robot arm related to the second substrate support,
a first sensor provided to the first substrate support, the first sensor being an edge sensor configured to sense for edge of a substrate, and
a second sensor arranged at a predetermined location with respect to the second substrate support, the second sensor being an optical sensor,
the method comprising calibrating the first robot arm and the second robot arm with respect to the first substrate support and the second substrate support using the second sensor.

2. The method of claim 1, wherein the second sensor is arranged adjacent to the second substrate support.

3. The method of claim 1, wherein the first substrate support is a pre-aligner system comprising functionality to measure and correct eccentricity and/or orientation of a substrate positioned on the first substrate support.

4. The method of claim 1, wherein the calibrating comprises calibrating a first end effector of the first robot arm and a second end effector of the second robot arm with respect to the second sensor.

5. The method of claim 4, wherein the calibrating the first end effector and the second end effector with respect to the second sensor comprises positioning a first opening of the first end effector and a second opening of the second end effector between an optical source and a sensor part of the second sensor.

6. The method of claim 1, wherein the calibrating comprises calibrating the second robot arm with respect to a substrate storage location using a third sensor provided at the storage location.

7. The method of claim 1, further comprising:
docking the first robot arm at the first substrate support;
using the second robot arm to pick up a substrate, and to move the substrate to the first substrate support;
positioning the substrate on the first substrate support;
using the first sensor and the first substrate support to center the substrate and direct the substrate in a predetermined orientation on the first substrate support; and
picking up the substrate from the first substrate support using the first robot arm.

8. The method of claim 7, further comprising:
using the first robot arm to move the substrate to the second substrate support;
using the second robot arm to pick up the substrate from the second substrate support, and to move the substrate to the first substrate support;
using the first sensor to measure the eccentricity of the substrate with respect to the first substrate support;
using the eccentricity to calculate an offset of the second robot arm; and
using the offset to calibrate the second robot arm with respect to the first substrate support.

9. The method of claim 8, further comprising:
determining a rotation of an unload robot coordinate system of the second robot arm with respect to a pre-aligner coordinate system of the first substrate support; and
correcting the rotation such that axes of the unload robot coordinate system are parallel to axes of the pre-aligner coordinate system.

10. The method of claim 1, further comprising:
using the second robot arm to pick up a substrate from a storage location;
move the substrate to the second sensor;
using the second sensor to detect a number of edge locations along a section of the periphery of the substrate;
using the number of edge locations to estimate a location of a central portion of the substrate;
using the second robot arm to position the substrate on the second substrate support;
move the second robot arm to the estimated location of the substrate central portion; and
using the second robot arm to pick up the substrate and move the substrate to the first substrate support.

11. The method of claim 10, wherein using the number of edge locations to estimate a location of the substrate central portion comprises using a least square circle regression.

12. The method of claim 10, further comprising:
using the first sensor to perform a first measurement of the eccentricity of the substrate with respect to the first substrate support;
using the second robot arm to move the substrate at least one step in a radial direction on the first substrate support; and
performing at least a second measurement of the eccentricity of the substrate with respect to the first substrate support;
using the first measurement and the at least one second measurement to calculate a second offset; and
using the second offset to calibrate the second robot arm with respect to the first substrate support.

13. The method of claim 12, wherein the at least one step in a radial direction is in the order of 1 mm.

14. A handler system for substrates, the handler comprising:
a first substrate support, comprising a first sensor being an edge sensor;
a first robot arm related to the first substrate support;
a second substrate support;
a second robot arm related to the second substrate support;
a second sensor, being an optical sensor, arranged at a predetermined location with respect to the second substrate support,
wherein the handler system is adapted to calibrate the first robot arm and the second robot arm with respect to the first substrate support and the second substrate support using the second sensor.

15. A lithographic system, comprising at least one lithographic apparatus connected to at least one handler system according to claim 14.

16. The handler system according to claim 14, wherein the second sensor is arranged adjacent to the second substrate support.

17. The handler system according to claim 14, wherein the first substrate support is a pre-aligner system comprising functionality to measure and correct eccentricity and/or orientation of a substrate positioned on the first substrate support.

18. The handler system according to claim 14, configured to calibrate a first end effector of the first robot arm and a second end effector of the second robot arm with respect to the second sensor.

19. The handler system according to claim 14, configured to calibrate the second robot arm with respect to a substrate storage location using a third sensor provided at the storage location.

20. The handler system according to claim 14, configured to cause:
docking of the first robot arm at the first substrate support;
use of the second robot arm to pick up a substrate, and to move the substrate to the first substrate support;
positioning of the substrate on the first substrate support;
use of the first sensor and the first substrate support to center the substrate and direct the substrate in a predetermined orientation on the first substrate support; and
picking up of the substrate from the first substrate support using the first robot arm.
